(19) United States
(12) Patent Application Publication
(10) Pub. No.: US 2009/0295385 A1
(43) Pub. Date: Dec. 3, 2009

(54) Magneto Sensor System and Method of Use

(76) Inventors: Audrius Brazdeikis, Missouri City, TX (US); Jaroslaw Wosik, Houston, TX (US); Morteza Naghavi, Houston, TX (US); Paul Cherukuri, Houston, TX (US)

Correspondence Address: ROBERT W STROZIER, P.L.L.C, PO BOX 429, BELLAIRE, TX, 77402-0429, US

(21) Appl. No.: 11/918,199

(22) PCT Filed: May 11, 2006
(86) PCT No.: PCT/US2006/018321

§ 371 Date: Mar. 16, 2009

Related U.S. Application Data
(60) Provisional application No. 60/679,830, filed on May 11, 2005.

(51) Int. Cl. G01R 33/44

(52) U.S. Cl. 324/309

(57) ABSTRACT

Instruments, systems and methods for using the instrument and systems are disclosed, where the systems include a magneto sensor, such as a superconducting quantum interference device (“SQUID”) and are designed to detect changes in a magnetic field in an animal including a human.

### RELATED APPLICATIONS

This application claims priority to PCT Patent Application Serial No. PCT/US06/18321, filed 11 May 2006 (May 11, 2006 or 11 May 2006) and published as WO/2006/122278 on 16 Nov. 2006 (Nov. 16, 2006 or 16 Nov. 2006), which claims priority to U.S. Provisional Patent Application Ser. No. 60/679,830, filed 11 May 2005 (May 11, 2006 or 11 May 2005).

### BACKGROUND OF THE INVENTION

1. Field of the Invention

The present invention relates to a system to detect changes in a magnetic field in an animal body, including a human.

More particularly, the present invention relates to a system for detecting changes in a magnetic field in an animal body, including a human body or patient, where the system includes a magneto sensor, such as a superconducting quantum interference device (SQUID) and a patient examination surface. The present invention also relates to methods of using a magneto sensor system of this invention to detect changes in a magnetic field in an animal including a human, to identify loci in the animal that accumulate magnetic particles or to identify vulnerable plaque in a cardiovascular system of the animal including a human.

2. Description of the Related Art

U.S. Pat. No. 5,735,279 to Klavenes, et al. disclosed the use of a magneto sensor magnetometer to detect magnetic changes in vivo. U.S. Pat. No. 6,027,946 to Weiteschies, et al. disclosed the use of a magneto sensor detector to measure the spatial distribution of relaxing magnetic markers in vivo. U.S. Pat. No. 5,594,849 to Kuc, et al. disclosed the use of magneto sensor magnetometers for measuring magnetic field intensity. U.S. Pat. No. 6,123,902 to Koch, et al. disclosed the use of a magneto sensor detector to detect small amounts of bound analytes in a solution. U.S. Pat. No. 6,048,515 to Kresse, et al. disclosed the use of nanoparticles comprising an iron containing core and a targeting polymer coating to determine the biological behavior of the nanoparticles.

However, there is still a need in the art for magneto sensor system, instruments incorporating such systems and methods using such systems for detecting changes in a magnetic field in animals including humans, especially animals with complex cardiovascular systems that are susceptible to cardiovascular diseases evidence by plaque formation in arteries and veins.

### SUMMARY OF THE INVENTION

The present invention provides a system for examining an animal or human patient including a magneto sensor component. Various embodiments of the present invention provide a patient examination surface and a magneto sensor associated therewith which can be moved relative to the body of the animal lying on the surface, thereby allowing examination of various portions of the animal's body using the magneto sensor. The embodiments can further include a magnetic shielding component.

The present invention also provides a system for examining an animal or human patient including a magneto sensor component and a component for generating an external magnetic field and optionally a magnetic shielding component.

The present invention also provides a system for examining an animal or human patient including a magneto sensor component and a component for imparting a mechanical vibration to the animal and optionally a magnetic shielding component.

The present invention also provides a system for examining an animal or human patient including a magneto sensor component, a component for generating an external magnetic field and a component for imparting a mechanical vibration to the animal and optionally a magnetic shielding component.

The present invention also provides methods of using a system of this invention to detect a magnetic profile of an animal including a human, where the method includes placing an area or region of interest of the animal adjacent a magnetic sensor and measuring a magnetic response of the area of interest. The method also includes administering a magnetically active agent such as magnetically active nanoparticles or another magnetically active materials to the animal and measuring a magnetic response during and/or after the administration of the magnetically active agent. The method of the present invention may be employed for various medical diagnostic purposes, such as locating vulnerable plaque in a patient's body.

The present invention also provides methods of using a system of this invention to detected magnetic profile of an animal including an human, where the method includes placing an area or region of interest of the animal adjacent a magnetic sensor and measuring a magnetic response of the area of interest. The method also includes administering a magnetically active agent such as magnetically active nanoparticles or another magnetically active materials to the animal and measuring a magnetic response during and/or after the administration of the magnetically active agent. The method also includes the step of exposing the patient to an external magnetic field before, during and/or after administration of the magnetically active agent. The method of the present invention may be employed for various medical diagnostic purposes, such as locating vulnerable plaque in a patient's body.

The present invention also provides methods of using a system of this invention to detected magnetic profile of an animal including an human, where the method includes placing an area or region of interest of the animal adjacent a magnetic sensor and measuring a magnetic response of the area of interest. The method also includes the steps of administering a magnetically active agent such as magnetically active nanoparticles or another magnetically active materials to the animal and measuring a magnetic response during and/or after the administration of the magnetically active agent. The method also includes the steps of exposing the patient to an external magnetic field before, during and/or after administration of the magnetically active agent. The method also includes the steps of exposing the patient to a source of mechanical vibration of tissue within the area of interested and measuring a magnetic response before, during and/or after administration of the magnetically active agent, where the mechanical vibration can be induces using ultrasonic probes operating at one or more frequencies. When the probes operate at two or more frequencies, mechanical vibrations at a frequency determined by the interference of the two or more ultrasonic frequencies result in the tissue allowing the mechanical vibration frequency in the tissue to be adjusted into a frequency range of the magnetic sensors to achieve improved coupling between the frequency range of the magnetic sensor and the mechanical vibration of the tissue. The method of the present invention may be employed for various medical diagnostic purposes, such as locating vulnerable plaque in a patient's body.

### BRIEF DESCRIPTION OF THE DRAWINGS

The invention can be better understood with reference to the following detailed description together with the appended illustrative drawings:

FIG. 1A is an isometric view of an embodiment of an apparatus of this invention;

FIG. 1B is an isometric view of another embodiment of an apparatus of this invention;

FIG. 1C is an isometric view of another embodiment of an apparatus of this invention;

FIG. 1D is an isometric view of another embodiment of an apparatus of this invention;

FIG. 1E is an isometric view of another embodiment of an apparatus of this invention;

FIG. 2 is an isometric view of another embodiment of an apparatus of this invention;

FIG. 3 is an isometric view of another embodiment of an apparatus of this invention;

FIG. 4 is a block diagram of a fourth method embodiment of the present invention;

FIG. 5 is a block diagram of a first method embodiment of the present invention;

FIGS. 6A&B are block diagrams of a second method embodiment of the present invention;

FIGS. 7A-D are block diagrams of a third method embodiment of the present invention;

FIGS. 8A&B are block diagrams of a fifth method embodiment of the present invention;

FIG. 9 is a block diagram of a sixth method embodiment of the present invention; and

FIG. 10 is a block diagram of a seventh method embodiment of the present invention.

### DETAILED DESCRIPTION OF THE INVENTION

The inventors have found new magneto sensors, instruments incorporating the sensors and method using the sensors can be constructed and implemented, where the magneto sensors are designed to measure a magnetic field distribution in an area of interest in an animal including a human. The instruments include a magnetic sensor mounted on an examination table or on a moving platform above the examination table, where the instruments can include magnetic shields adapted to shield the area of interest from unwanted external magnetic fields and a magnetic generator for generating a controlled external magnetic field for modulating the magnetic distribution. The magnetic field distribution measuring step can be performed before, during and/or after the administration of a magnetically active agent to the animal either orally, intra-arterially, intravenously, via direct injection to the area of interest or via any other suitable administration process.

The present invention broadly relates to an instrument or an apparatus including an examination table or chair and a magnetic sensor unit, where the unit is designed to be positioned adjacent to an area of interest of an animal including a human situated on the examination table or in the examination chair. The instruments can include a magnetic shield, legs with wheel assemblies for ready movability, slots for changing a position of the magnetic sensor relative to a body positioned on the table or in the chair, or a rotatable platform upon which the magnetic sensor unit is disposed so that it can be freely positioned above any area of interest in the animal. The apparatus are designed to be used with the administration of magnetically active agents into the animal.

The present invention broadly relates to method including the steps of measuring a magnetic field distribution via a magnetic sensor unit positioned adjacent an area of interest in an animal including a human before, during and/or after the administration of a magnetically active agent such as magnetically active nanoparticles. The method can also include inducing a physical stress to the animal and measuring a magnetic field distribution before, during and/or after agent administration and during physical stress. The method can also include applying a controlled external magnetic field and measuring a magnetic field distribution before, during and/or after of agent administration and/or stress. The method can also include imaging the area of interest and correlating spatial data from the images to register the magnetic field distribution data with structures. The method can also include ultrasound stimulation of the magnetically active agent to improve detection of accumulated agents within the area of interest.

### Suitable Materials and Sensors

Suitable magneto or magnetic sensors for use in this invention include, without limitation, magneto optical sensors, flux gate magnetometers, Hall effect sensors, magnetic force sensors, magneto resistive sensors, magneto inductive sensors, magneto-resonance sensors, superconducting quantum interference device (SQUID) and/or mixtures or combinations thereof.

Suitable magnetically active agents for use in this invention include, without limitation, magnetic substances, such as molecules or particles, iron oxide or gadolinium containing materials, especially, nanomaterials-nanoparticles or the like, SPIO particles, ferromagnetic molecules or particles, ferrimagnetic molecules or particles, paramagnetic molecules, paramagnetic particles or mixtures or combinations thereof.

Instruments of this Invention

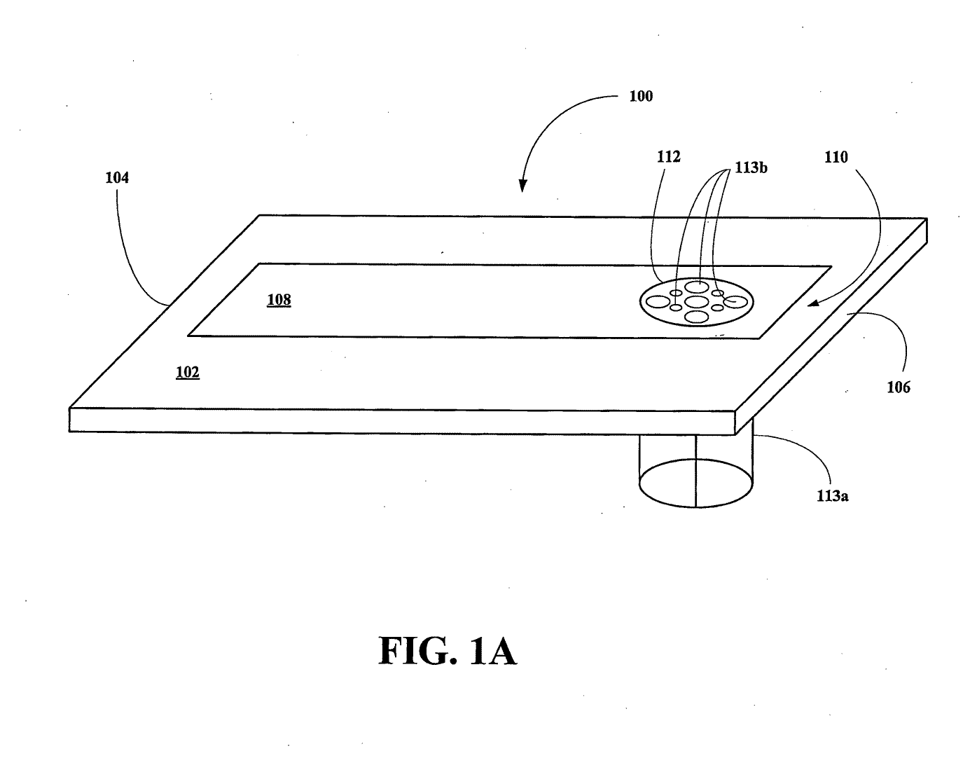

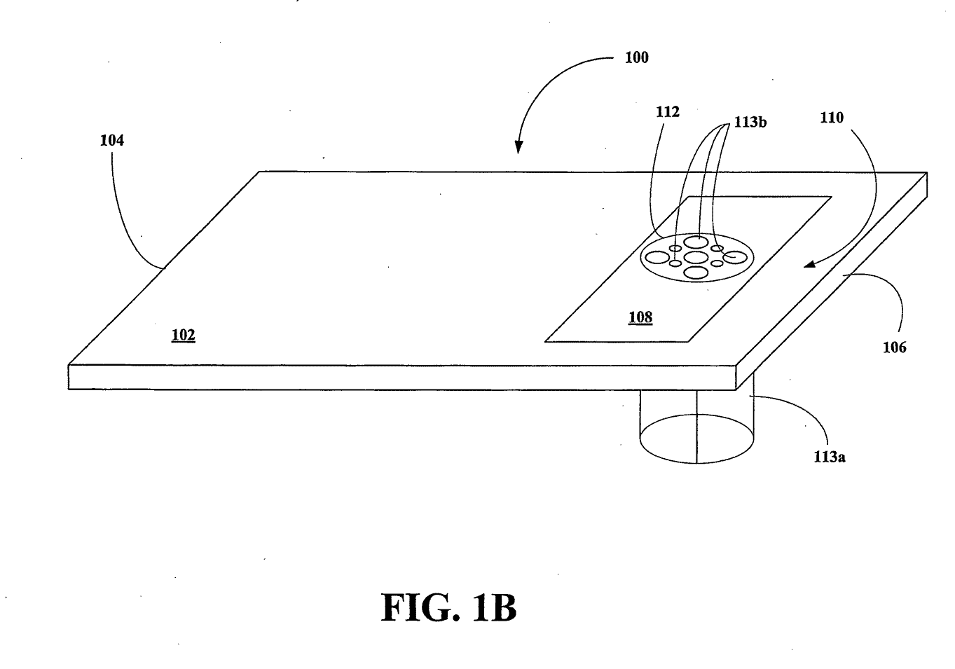

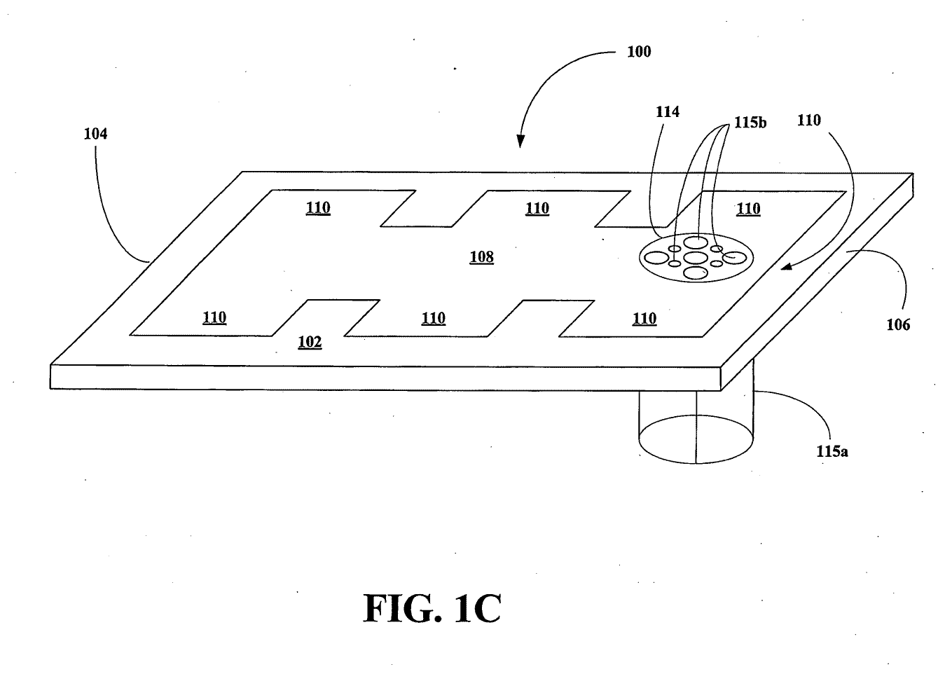

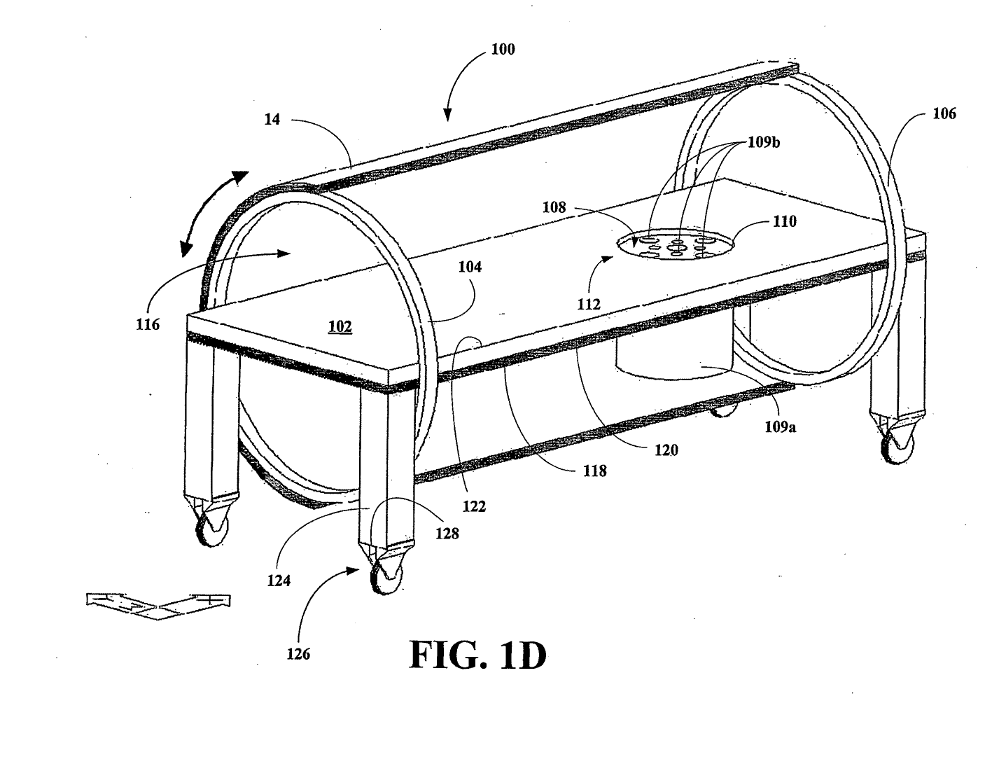

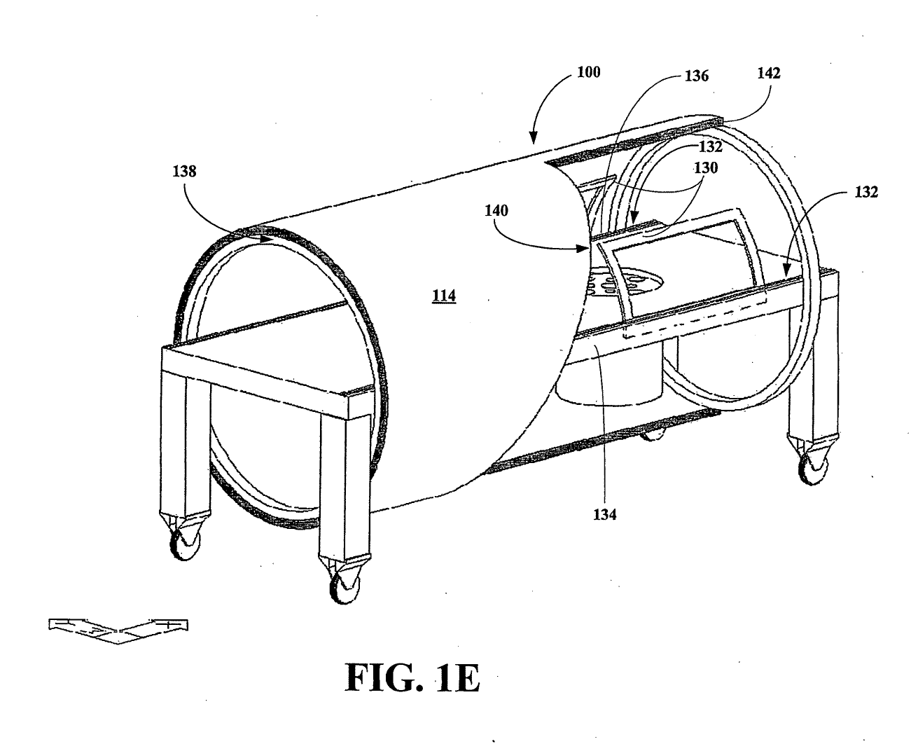

Referring now to FIG. 1A, an embodiment of an instrument of the present invention, generally 100, is shown. The instrument 100 includes a patient examination table 102 comprising a proximal end 104 and a distal end 106. The examination table 102 also includes an interior slot 108 extending longitudinally in a central region 110 of the table 102. The instrument 100 also includes a magnetic sensor unit 112 mounted within the slot 108 so that the unit 112 can be moved along a length of the slot 108. The movability of the unit 112 allows the unit 112 to be positioned adjacent an area of interest of an animal including a human placed on the examination table 102. The magnetic sensor unit 112 includes a housing 113a, which is generally a cryogenic housing such as a Dewar, and a plurality of magneto or magnetic sensors 113b.

Referring now to FIG. 1B, another embodiment of an instrument of the present invention, generally 100, is shown a patient examination table 102 comprising a proximal end 104 and a distal end 106. The examination table 102 also includes an interior slot 108 extending laterally in a distal region 110 of the table 102. The instrument 100 also includes a magnetic sensor unit 112 mounted within the slot 108 so that the unit 112 can be moved along a length of the slot 108. The movability of the unit 112 allows the unit 112 to be adjusted laterally so as to properly position the unit 112 adjacent an area of interest such as a chest region of animal including a human placed on the examination table 102. The magnetic sensor unit 112 includes a housing 113a, which is generally a cryogenic housing such as a Dewar, and a plurality of magneto or magnetic sensors 113b.

Referring now to FIG. 1C, another embodiment of an instrument of the present invention, generally 100, is shown a patient examination table 102 comprising a proximal end 104 and a distal end 106. The examination table 102 also includes a complex interior slot 108 extending longitudinally with laterally extensions 110 in a central region 112 of the table 102. The instrument 100 also includes a magnetic sensor unit 114 mounted within the slot 108 so that the unit 114 can be moved along a longitudinally along a length of the slot 108. At the lateral extensions 110, the unit 114 can also be adjusted laterally. This type of movability of the unit 114 allows the unit 114 to be properly positioned both longitudinally and laterally adjacent an area of interest of and animal including a human placed on the examination table 102. The magnetic sensor unit 112 includes a housing 115a, which is generally a cryogenic housing such as a Dewar, and a plurality of magneto or magnetic sensors 115b.

Referring now to FIG. 1D, another embodiment of an instrument of the present invention, generally 100, is shown designed primarily for magnetically sensing a chest region of a patient. The instrument 100 includes a patient examination table 102, a first or foot ring 104 and a second or head ring 106. The rings 104 and 106 are mounted on the table 102 so that the rings 104 and 106 can be rotated relative to the table 102. The instrument 100 also includes a magnetic sensor unit 108 mounted in an aperture 110 located in a central distal region 112 of the table 102. The magnetic sensor unit 108 includes a housing 109a, which is generally a cryogenic housing such as a Dewar, and a plurality of magneto or magnetic sensors 109b. The instrument 100 also includes a magnetic shield 114 mounted on the rings 104 and 106 and extending over about ½ of a circumference of the rings 104 and 106. Because the rings 104 and 106 are rotationally mounted on the table 102, when the shield 114 is positioned below the table 102, it allowing a patient to be positioned on the examination table 102 and then the shield 114 can be rotated into place to enclose the patient within an interior 116 of the instrument 100 and to partially magnetically isolate the patient from unwanted external magnetic fields. Thus, the shield 114 can be positioned in a first position above and adjacent to a patient lying on the examination table 102 or a second position below the examination table 102 for patient ingress and egress from the instrument 100. By rotating one or both of the rings 104 and 106, the shield 114 moves in an arc like motion as evidenced by the arrow between its first position to its second position. The shield may be mounted directly to the examination table or, alternatively, it may be attached or mounted to one or more components that are attached, or mounted directly, or indirectly, to the examination table. The instrument may also include a second magnetic shield 118 mounted on the examination table 102. Although the second shield 118 is shown mounted to a bottom surface 120 of the table 102, the shield may be mounted on a top surface 122 of the table 102 (not shown). Moreover, the second magnetic shield 118 may simply be an integral part of the table 102, being disposed on the top, bottom or in the middle of the table. The instrument 100 may also include a plurality of legs 124 (four shown in the figure) having wheel assembly 126 at their distal end 128 so that the instrument 100 can be movable.

Referring now to FIG. 1E, another embodiment of an instrument of the present invention, generally 100, is shown to include all of the features of the embodiment of FIG. 1D and further at least two magnetizing coils 130 mounted to the examination table 102. Although the coils 130 can be fixed, the coils 130 shown here are moveable along longitudinal slots 132 disposed near a right edge 134 and a left edge 136 of the table 102. The coils 130 are designed to expose the patient on the table 102 to a controlled external magnetic field to augment the measured magnetic profile of the patient as detected by the magnetic sensor unit 108. The coils 130 can produce any desired magnetic field including, without limitation, a static magnetic field, an amplitude varying magnetic field, a gradient magnetic field, a periodically varying magnetic field or any other type of combination or such field. For example, the coils 130 could produce a magnetic field that included a static compound and a time varying component or a field with one or more time varying features. The shield 114 of this embodiment comprises a cylinder 138 having a trapezoidal section 140 cut out a distal end 142 of the cylinder 138. Again, the shield 114 is rotatable to facilitate ingress and egress from the interior the instrument 100.

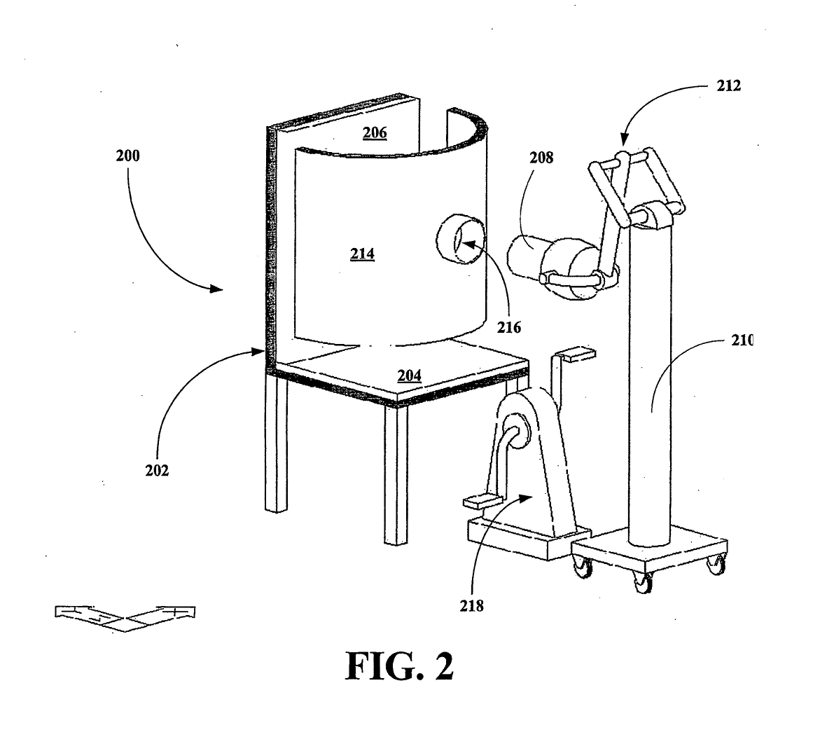

Referring now to FIG. 2, another embodiment of an instrument of this invention, generally 200, is shown designed primarily for magnetically sensing a chest region of a patient, when the patient is a rest, during stress and after stress. The instrument 200 includes a chair 202 comprising a first surface 204 oriented in a substantially horizontal position and a second surface 206 oriented in a substantially vertical position. The invention further comprises a magnetic sensor unit 208 mounted on a movable stand 210. In the embodiment, the magnetic sensor 208 is mounted to the stand 210 via an adjustable arm assembly 212. The instrument 200 may also include a magnetic shield 214 disposed vertically adjacent the vertical surface 206. The shield 214 includes an aperture 216 into which the magnetic sensor 208 is inserted to bring the sensor 208 into proximity with a patient sitting the chair 202 in a chest region of the patient. The instrument 200 may also include an exercise device 218, here a stationary bicycle, for inducing a physical stress on the patient so that a magnetic field distribution during stress can be acquired after magnetically active agent administration or before and after magnetically active administration. The instrument 200 can also includes a second magnetic shield 220 associated with or integral with the chair 202 and being coextensive with the horizontal surface 204 and the vertical surface 206. In this embodiment, the sensor is adapted to be moveable such that it can be positioned adjacent to the heart of a patient seated on the first surface.

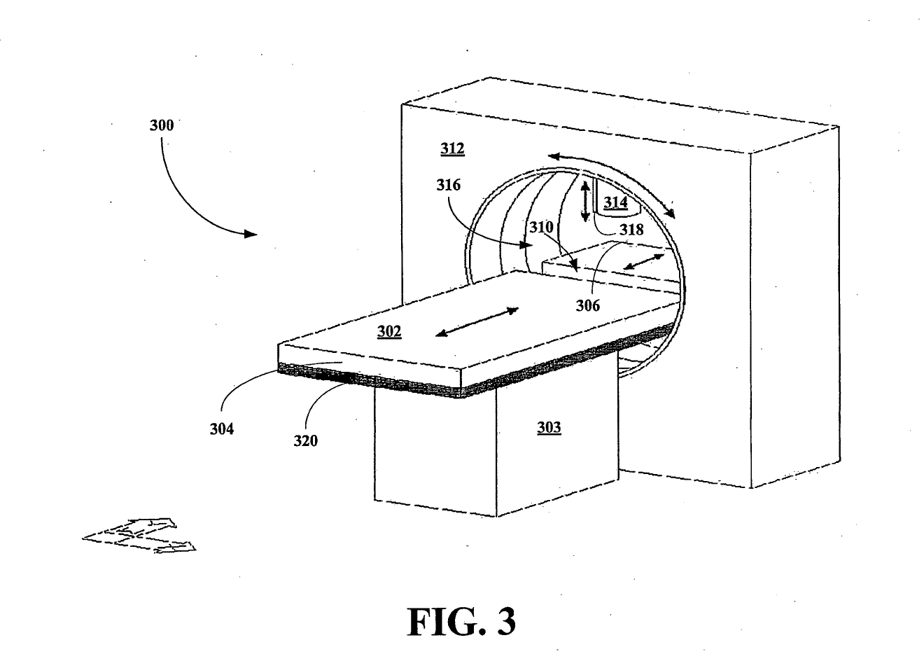

Referring now to FIG. 3, another embodiment of an instrument of this invention, generally 300, is shown to includes a patient examination table 302 having a first end 304 and second end 306 opposite the first end 304 and supported on a support member 303. The table 302 is moveable along a longitudinal axis 308 extending from the first end 304 to the second end 306. The table 302 also includes an opening 310 located near the second end 306. The instrument 300 further includes a sensor mounting receptacle 312 positioned adjacent the examination table 302 and surrounding the opening 310 in the table 302 near is second end 306. The instrument 300 also includes a magnetic sensor 314 mounted on the mounting receptacle 312 such that the sensor 314 can be rotationally moved about an examination region 316 as shown by the rotation arrow. The sensor 314 is also moveable in a radial direction as shown by the vertical arrow so that the sensor 314 can be rotated it a proper position and then the sensor 314 can be lowered to a desired position above the an area of interest of a patient lying on the table 302. The instrument 300 may also include an ultrasound probe 318 that is also vertically positionable so that it can be brought into direct contact with a location of a patient's body near the area of interest. Of course, it should be recognized that the ultrasound probe can be integrated into the sensor 314 and designed to be extendable from the sensor 314 to contact the location. Additionally, the instrument 300 can includes a plurality of such probes 318. Furthermore, the receptacle 312 can also house an imaging instrument so that the patient can be simultaneously imaged. In this embodiment, the sensor is rotatable in a closed loop path about the examination region. The closed loop can be circular. In another embodiment, the sensor 314 can be mounted on an adjustable arm mounted on the receptacle 312 as shown in FIG. 2. In another embodiment, the sensor 314 mounted on the receptacle so that it is moveable along an axis parallel to the longitudinal axis. In all of the various embodiments of the instrument 300, the table 302 can also include a magnetic shield 320 associated (disposed on a bottom or top surface) or integral therewith.

### Method for Using the Systems of This Invention

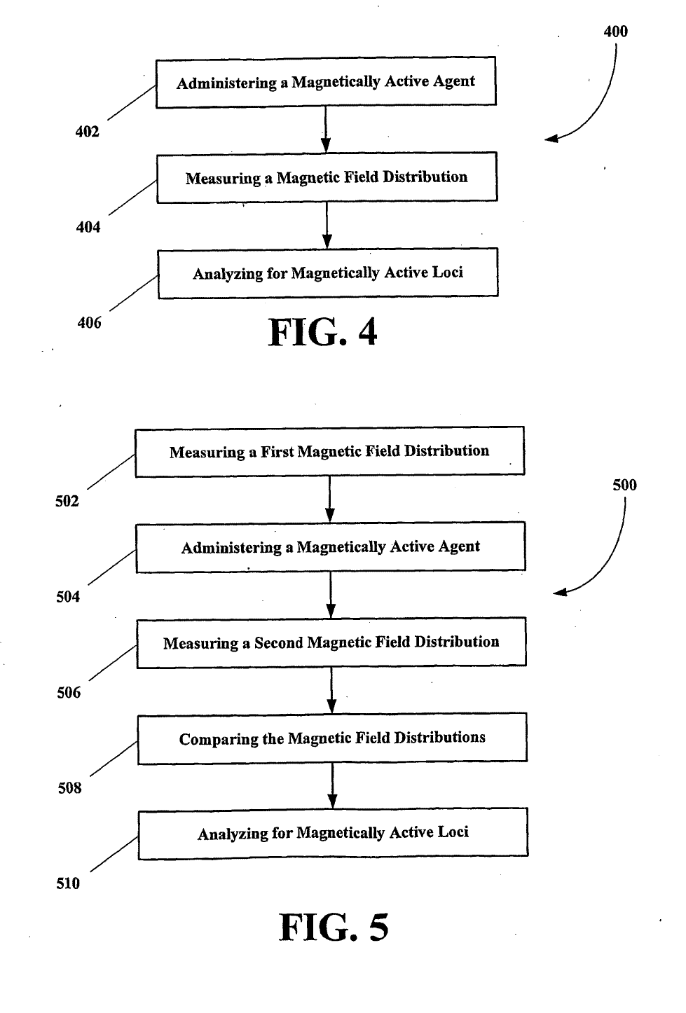

Referring now to FIG. 4, an embodiment of a method of this invention for identifying magnetically active loci in a body of an animal including a human, generally 400, is shown to include an administering step 402, where a magnetically active agent is administered to the animal. After administration, the method also includes a measuring step 404, where a magnetic field distribution of an area of interest of the animal is measured using a magneto sensor. When a magnetically active agent, such as magnetic or magnetizable nanoparticles are administered into an animal be any known administration protocol, the agent distributes itself throughout the animal over time. Fortunately, the distribution is no uniform, as no diagnostic information could be retrieved from the magnetic field distribution if the distribution was uniform. Because different tissues, structures or locations within the entire animal, and especially with in the area of interest, accumulate the agent differently, the distribution is capable of identifying location or loci having high accumulations of the agent. These loci are believed to be associated with tissue structures that are not capable of readily eliminating the agent. Such loci include locations associated with ischemia, infarction, injury, inflammation, infection, tumor, bleeding, angiogenesis, abnormally high blood barrier permeability, abnormally high capillary permeability, clot formation, plaque, vulnerable plaque or other structures that accumulate the agent. After measuring the magnetic field, the method includes an analyzing step 406, where the distribution is analyzed to determine loci or locations within the area of interest that have relatively high accumulations of the agent relative to other locations in the area of interest.

Referring now to FIG. 5, another embodiment of a method of this invention for identifying magnetically active loci in a body of an animal including a human, generally 500, is shown to include a first measuring step 502, where a first magnetic field distribution of an area or region of interest in the animal is measured using a magneto sensor located external to the animal. After the first magnetic field distribution is measured, the method includes an administering step 504, where a magnetically active agent is administered to the animal. After administration, the method also includes a second measuring step 506, where a second magnetic field distribution of an area of interest of the animal is measured using the magneto sensor located external to the animal. Next, the method includes a comparing step 508, where the first and second distributions are compared. The method also includes an analyzing step 510, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself. The comparison of a first and second magnetic field distributions includes information about the distribution of the magnetically active agent within the area of interest. The comparison can be a subtraction of the data after spatial registry so that the distribution relate to the same features in the area of interest. To aid in spatial registry, elements of known magnetic field behavior can be positioned on the body to assist in data analysis and data registry, especially in during the reverse transforms, where known spatial elements can be used to adjust the boundary conditions.

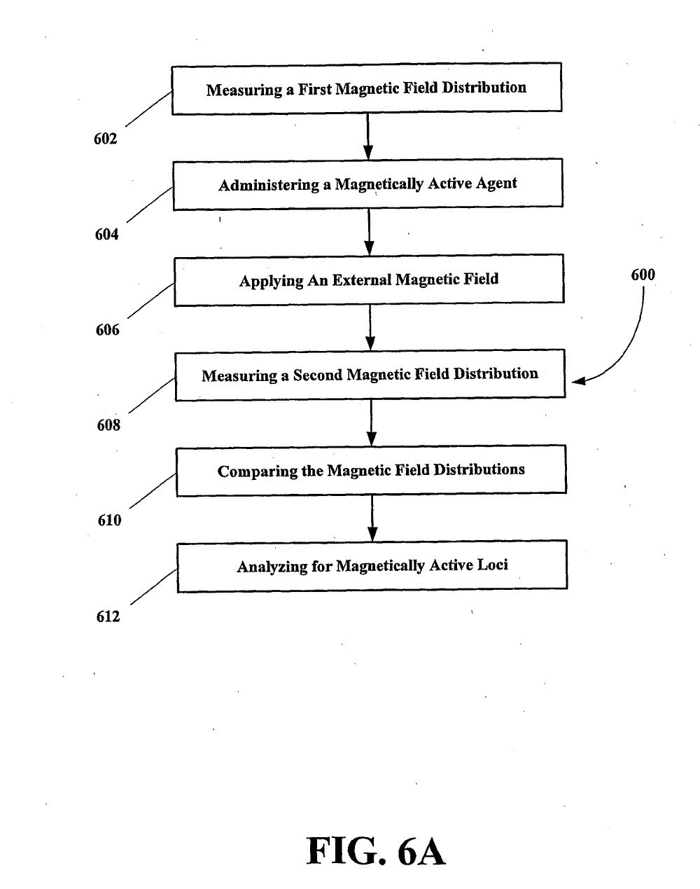

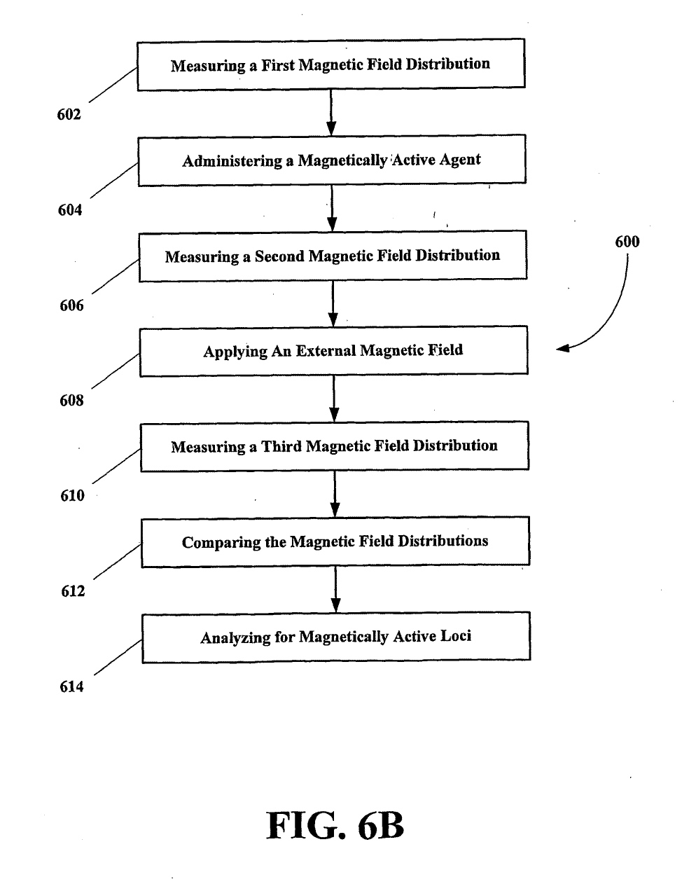

Referring now to FIG. 6A, another embodiment of a method of this invention for identifying magnetically active loci in a body of an animal including a human, generally 600, is shown to include a first measuring step 602, where a first magnetic field distribution of an area or region of interest in the animal is measured using a magneto sensor located external to the animal. After the first magnetic field distribution is measured, the method includes an administering step 604, where a magnetically active agent is administered to the animal. After administration, the method also includes an applying an external magnetic field step 606, where the area of interest is exposed to an external magnetic field. While the area of interest is being exposed to the external magnetic field, the method includes a second measuring step 608, where a second magnetic field distribution of an area of interest of the animal is measured using the magneto sensor located external to the animal. Next, the method includes a comparing step 610, where the first and second distributions are compared. The method also includes an analyzing step 612, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself.

Referring now to FIG. 6B, another embodiment of a method of this invention for identifying magnetically active loci in a body of an animal including a human, generally 600, is shown to include a first measuring step 602, where a first magnetic field distribution of an area or region of interest in the animal is measured using a magneto sensor located external to the animal. After the first magnetic field distribution is measured, the method includes an administering step 604, where a magnetically active agent is administered to the animal. After administration, the method also includes a second measuring step 606, where a second magnetic field distribution of an area of interest of the animal is measured using the magneto sensor located external to the animal. Next, the method includes an applying an external magnetic field step 608, where the area of interest is exposed to an external magnetic field. While the area of interest is being exposed to the external magnetic field, the method includes a third measuring step 610, where a third magnetic field distribution of an area of interest of the animal is measured using the magneto sensor located external to the animal. Next, the method includes a comparing step 612, where the first, second and third distributions are compared. The method also includes an analyzing step 614, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself.

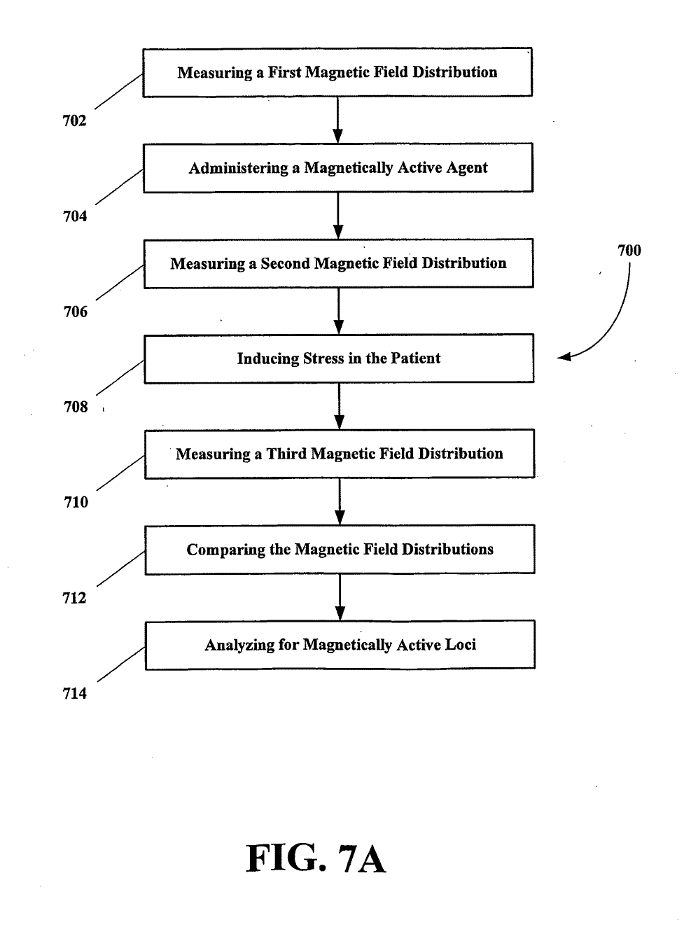

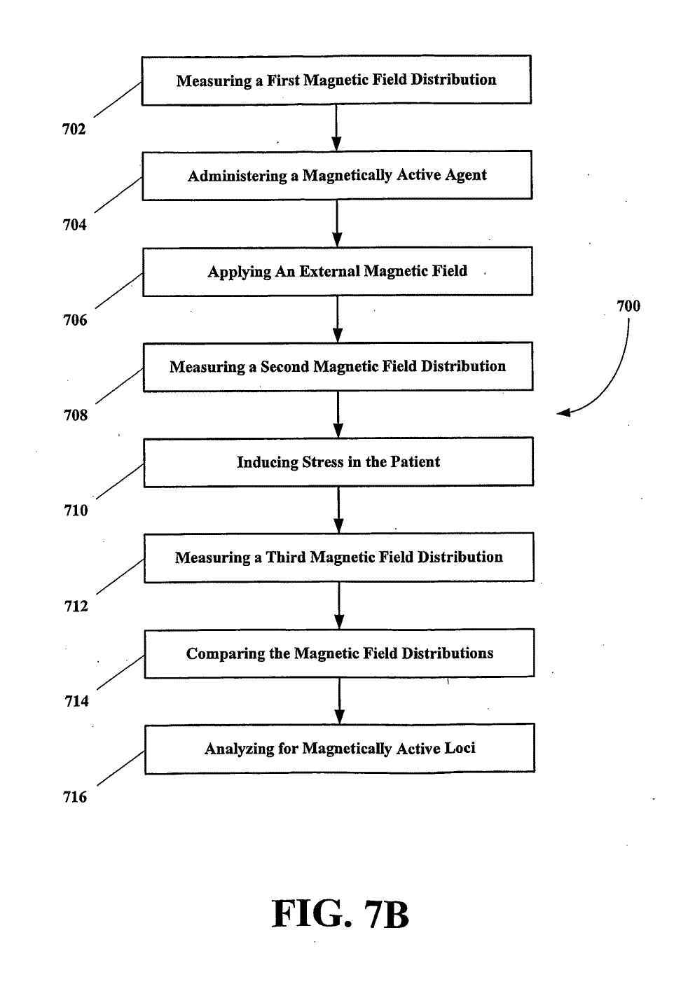

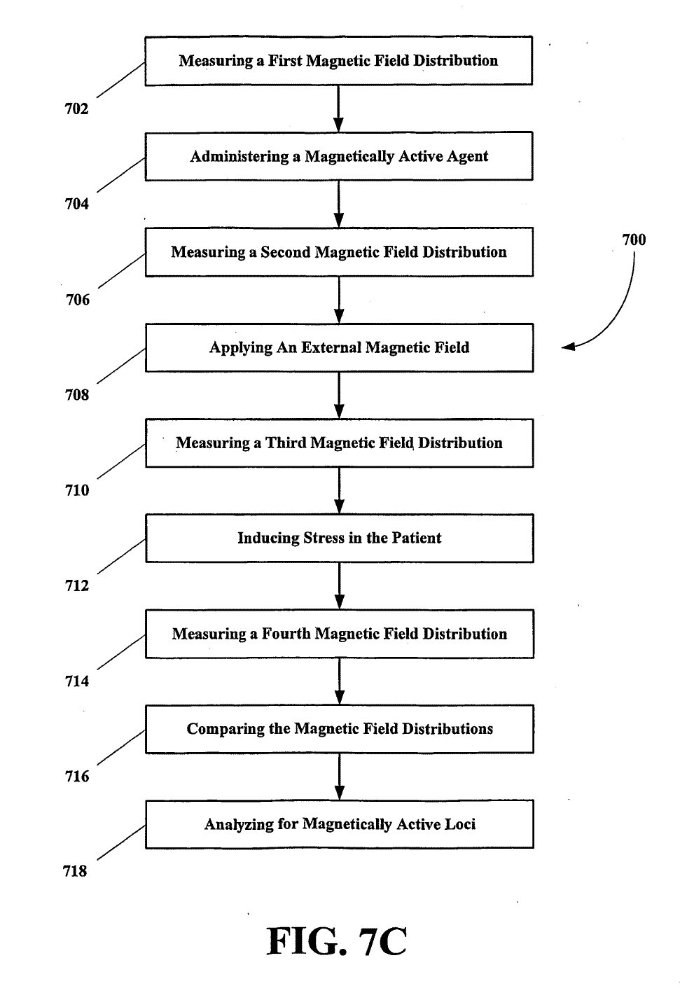

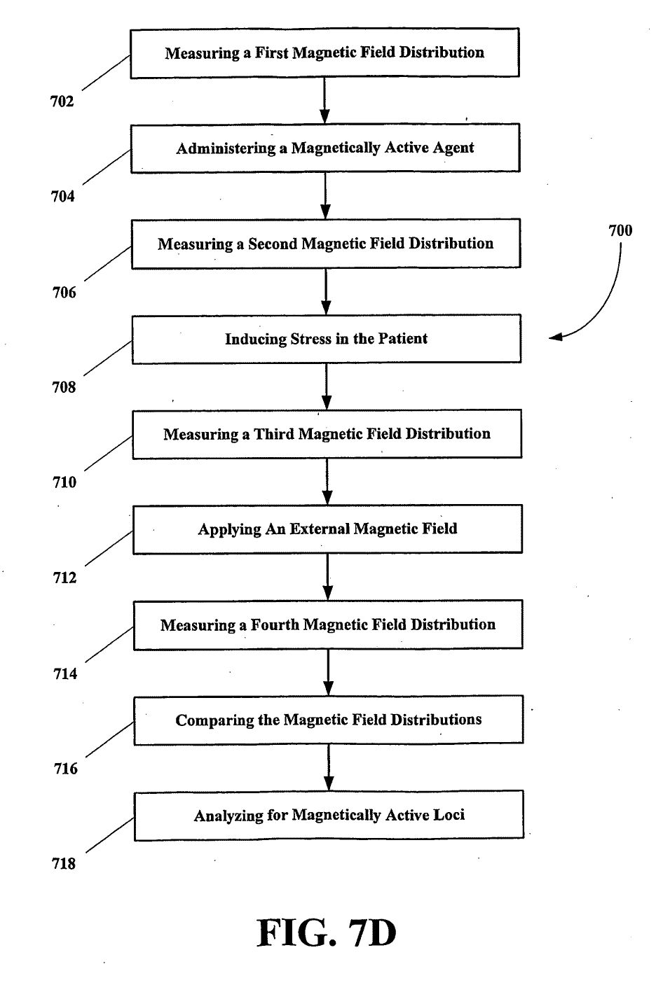

Referring now to FIG. 7A, another embodiment of a method of this invention for identifying magnetically active loci in a body of an animal including a human, generally 700, is shown to include a first measuring step 702, where a first magnetic field distribution of an area or region of interest in the animal is measured using a magneto sensor located external to the animal. After the first magnetic field distribution is measured, the method includes an administering step 704, where a magnetically active agent is administered to the animal. After administration, the method includes a second measuring step 706, where a second magnetic field distribution of an area of interest of the animal is measured using the magneto sensor located external to the animal. The method also includes an inducing a stress step 708, where the animal is required to undergo a physical stress such riding an exercise bike. While under the physical stress, the method includes a third measuring step 710, where a third magnetic field distribution of an area of interest of the animal is measured using the magneto sensor located external to the animal. Next, the method includes a comparing step 712, where the first and second distributions are compared. The method also includes an analyzing step 714, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself. The comparisons of the second and third distributions will evidence any change in the distribution do to physical exertion.

Referring now to FIG. 7B, another embodiment of a method of this invention for identifying magnetically active loci in a body of an animal including a human, generally 700, is shown to include a first measuring step 702, where a first magnetic field distribution of an area or region of interest in the animal is measured using a magneto sensor located external to the animal. After the first magnetic field distribution is measured, the method includes an administering step 704, where a magnetically active agent is administered to the animal. After administration, the method includes an applying an external magnetic field step 706, where the area of interest is exposed to an external magnetic field. While the area of interest is being exposed to the external magnetic field, the method includes a third measuring step 708, where a third magnetic field distribution of an area of interest of the animal is measured using the magneto sensor located external to the animal. The method also includes an inducing a stress step 710, where the animal is required to undergo a physical stress such riding an exercise bike. While under the physical stress and while in the absence or the presence of the external magnetic field, the method includes a third measuring step 712, where a third magnetic field distribution of an area of interest of the animal is measured using the magneto sensor located external to the animal. Next, the method includes a comparing step 714, where the first, second and third distributions are compared. The method also includes an analyzing step 716, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself.

Referring now to FIG. 7C, another embodiment of a method of this invention for identifying magnetically active loci in a body of an animal including a human, generally 700, is shown to include a first measuring step 702, where a first magnetic field distribution of an area or region of interest in the animal is measured using a magneto sensor located external to the animal. After the first magnetic field distribution is measured, the method includes an administering step 704, where a magnetically active agent is administered to the animal. After administration, the method includes a second measuring step 706, where a second magnetic field distribution of an area of interest of the animal is measured using the magneto sensor located external to the animal. Next, the method also includes an applying an external magnetic field step 708, where the area of interest is exposed to an external magnetic field. While the area of interest is being exposed to the external magnetic field, the method includes a third measuring step 710, where a second magnetic field distribution of an area of interest of the animal is measured using the magneto sensor located external to the animal. The method also includes an inducing a stress step 712, where the animal is required to undergo a physical stress such riding an exercise bike. While under the physical stress and while in the absence or the presence of the external magnetic field, the method includes a fourth measuring step 714, where a third magnetic field distribution of an area of interest of the animal is measured using the magneto sensor located external to the animal. Next, the method includes a comparing step 716, where the first and second distributions are compared. The method also includes an analyzing step 718, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself.

Referring now to FIG. 7D, another embodiment of a method of this invention for identifying magnetically active loci in a body of an animal including a human, generally 700, is shown to include a first measuring step 702, where a first magnetic field distribution of an area or region of interest in the animal is measured using a magneto sensor located external to the animal. After the first magnetic field distribution is measured, the method includes an administering step 704, where a magnetically active agent is administered to the animal. After administration, the method also includes a second measuring step 706, where a second magnetic field distribution of an area of interest of the animal is measured using the magneto sensor located external to the animal. The method also includes an inducing a stress step 708, where the animal is required to undergo a physical stress such riding an exercise bike. While under the physical stress and while in the absence or the presence of the external magnetic field, the method includes a third measuring step 710, where a third magnetic field distribution of an area of interest of the animal is measured using the magneto sensor located external to the animal. Next, the method includes an applying an external magnetic field step 712, where the area of interest is exposed to an external magnetic field. While the area of interest is being exposed to the external magnetic field, the method includes a fourth measuring step 714, where a third magnetic field distribution of an area of interest of the animal is measured using the magneto sensor located external to the animal. Next, the method includes a comparing step 716, where the first, second and third distributions are compared. The method also includes an analyzing step 718, where the distributions and comparison are analyzed to determine loci within the area of interest having an accumulation of the magnetically active agent above a threshold accumulation amount. The threshold can be determined relative to a reference scale or can be determined from a scale produced from the distribution itself or from a combination of a reference scale and corrections factors taken from the distribution itself. It should be recognized by ordinary artisans that the exact sequence of steps for acquiring distributions of interests can be varied from those disclosed above, e.g., some of the distributions measures can be absent or additional distributions can be added. For example, a distribution can be acquired during the administration to obtain some temporal data as to the rate of accumulations of the agent in different loci in the area of interest.

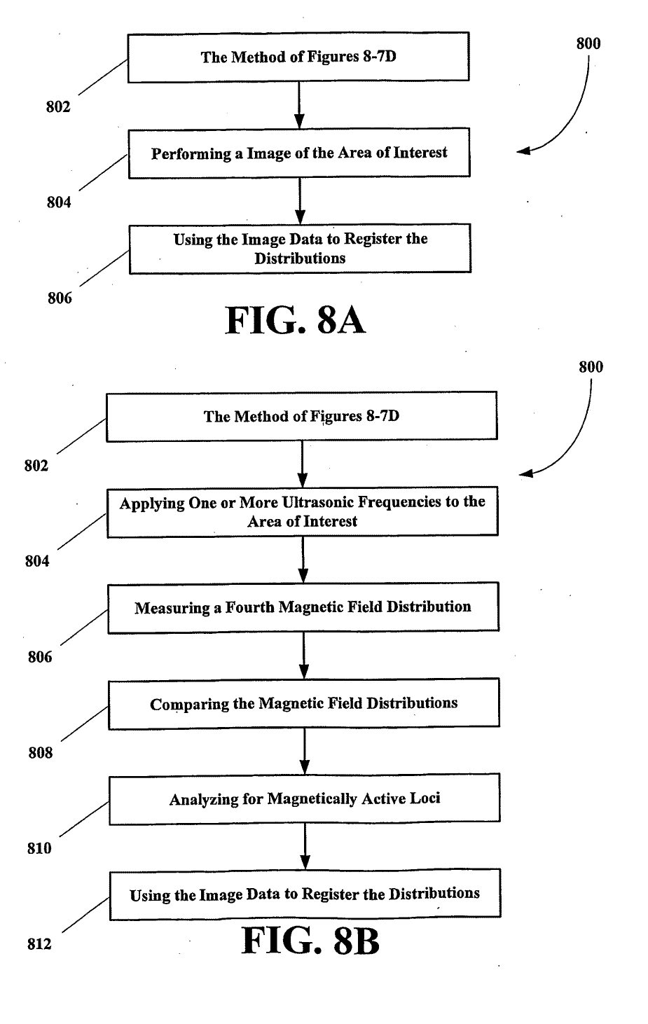

Referring now to FIG. 8A, another embodiment of methods of this invention for identifying magnetically active loci in a body of an animal including a human, generally 800, are shown to include any of the previous method 802, with the addition of a imaging step 804 and a registering step 806. The imaging step 804 is adapted to couple the magnetic fluid distribution data with data from an imaging method such as magnetic resonance imaging (MRI), CAT scan imaging, computed tomography imaging, standard X-Ray imaging, ultrasonic or ultrasound imaging, or any other imaging method for obtaining a spatially relevant image. The registering step 806 is adapted to use the spatially relevant image data to associate the loci identified in the magnetic field distributions with their associated structures in the spatial image.

Referring now to FIG. 8B, another embodiment of methods of this invention for identifying magnetically active loci in a body of an animal including a human, generally 800, are shown to include any of the previous method 802, with the addition of an ultrasonic irradiating step 804, an additional measuring step 806, an additional comparing step 808, an additional analyzing step 810 and a registering step 812. This method includes exciting the area of interest where the magnetic field distribution is being measured using ultrasound energy, while the distribution is being measured. The ultrasonic energy can be a single frequency and imparts a mechanical displacement to the magnetically active agents so that they can be more easily discerned from the magnetic fields generated by structures in the area of interest that generate their own magnetic field that tend to vary with time. The ultrasound energy can include two or more frequencies, where the frequencies are designed to interfere producing a mechanical vibration at a desired frequency such as at a beat frequency resulting from their interference. By carefully selecting the beat frequency, the mechanical vibration frequency can be adjusted from the megahertz range, which is the range generated by ultrasound devices, into a frequency range between 1 Hz and 100,000 Hz. The above methods also includes a changing a property of the applied magnetic field step, where one or more properties of the applied external magnetic field are changed in a controlled manner to enhance detection of the magnetically active agent in the area of interest, especially loci evidencing an accumulation of the agent. The properties of the field that can be changed include direction, duration, frequency and/or intensity. The methods can also include measuring the magnetic field distribution before and after the changes.

This disclosure also discloses method and apparatus for detection, preferably with a superconducting quantum interference device magnetometer, of weak magnetic field variations originating from accumulated magnetic nanoparticles in electrically active tissues or body organs such as the heart. A difficulty in detecting accumulations magnetically active agents, such as magnetic nanoparticles, in such tissues is the presence of much stronger background magnetic fields in the tissues or generated in the tissues, e.g., the magnetic fields associated with cyclic bioelectrical activity of the heart. These generated or inherent magnetic field tend to mask, overshadow or obscure simultaneous detection of small local magnetic field perturbations to an applied magnetic field due to the accumulated magnetically active agents in these tissues. The another method of this invention includes the steps of using a pre-detection polarization of magnetic nanoparticles followed by discriminating detection of induced magnetic field perturbations within total measured flux. The pre-detection polarization sequence includes of time-varying excitation signal that is repeatedly triggered in a synchronized manner with a selected interval of a cardiac cycle and transmitted to whole body or local area of interest through a set of magnetic excitation coils or an acoustic beam transmitter. The detection is performed in a narrow frequency band, typically near a fundamental excitation frequency during the selected interval of the cardiac cycle.

One embodiment of this method for measuring weak magnetic field perturbations due to locally accumulated magnetically active agents such as magnetically active nanoparticles at a target location, includes the steps of:
I. placing a magnetometer in the proximity of an area of interest of an animal, including an human;
ii. monitoring cardiac activity electrically or magnetically of the animal;
iii. determining a beginning of a trigger signal interval, to by analyzing a cardiac cycle waveform of the animal;
iv. determining a duration, t_{d} of the trigger signal interval;
v. generating a trigger signal waveform using parameters determined in steps (iii) and (iv);
vi. transmitting the trigger signal waveform to an arbitrary-form signal generator in order to generate an excitation signal waveform of chosen duration at the end of trigger;
vii. transmitting the excitation signal waveform through an excitation coil setup in order to achieve a required polarization of magnetic moments of nanoparticles;
viii. repeating steps (ii) through (vii);
ix. detecting a biomagnetic signal at the magnetometer;
x. extracting data from the selected interval of the cardiac cycle that equals a length of the excitation signal waveform;
xi. transforming the data from step (x) into a data form which indicates presence of nanoparticles at the target location.

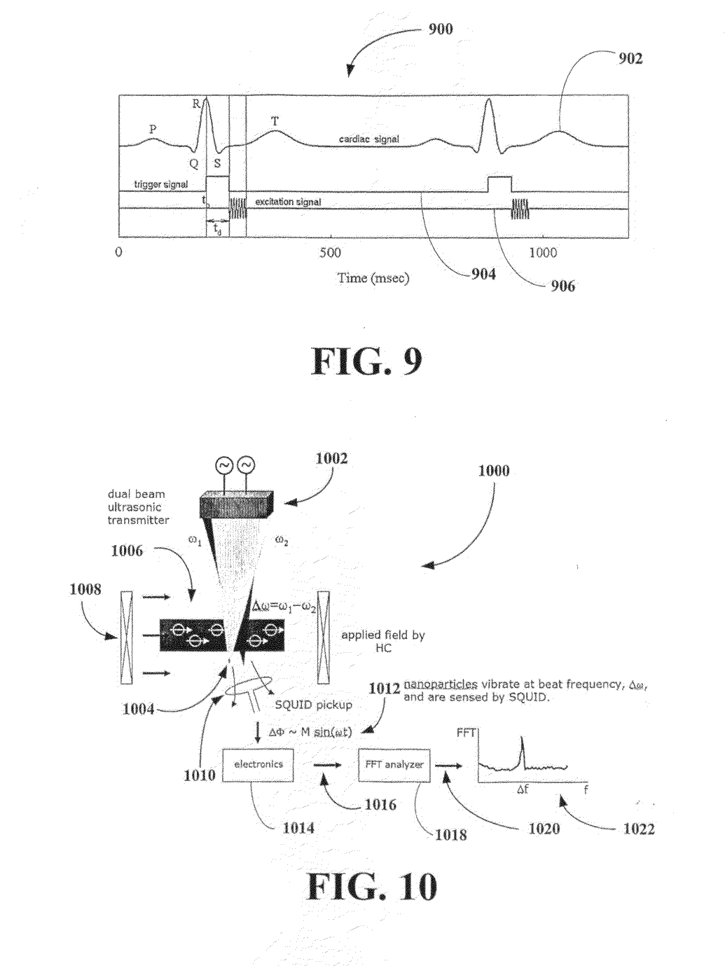

Referring now to FIG. 9, the above method is illustrated graphically 900. The figure includes a cardiac cycle graph 902 with associated cardiac cycle designators P, Q, R, S and T. Shown immediately under the cardiac cycle graph 902 is an example of a trigger signal 904 including intervals, tₒ having a duration t_{d}. Immediately below the trigger signal 904 is shown an example of an excitation signal 906. The trigger signal and the excitation signal are adapted to occur in a relatively quick part or portion of the cardiac cycle. By a judicious selection of the trigger signal and the excitation signal one can minimize the interference from naturally generated magnetic fields and can simultaneously maximize the detection of the small magnetic perturbations due to the magnetically active agents accumulated in the tissue. The trigger signal and excitation signal can be controlled by a lock-in amplifier and lock-in detection systems can be used to further improve the detection of the small magnetic perturbations due to the magnetically active agents accumulated in the tissue.

The second embodiment of this type of method of the present invention for measuring weak magnetic field perturbations due to locally accumulated magnetically active agents such as nanoparticles at a target location, includes the steps of:
I. placing magnetomer in the proximity of the body;
ii. inserting acoustic radiation force at a target location by an ultrasonic transducer using dual beam ultrasonic transmitter to generate a mechanical vibration of the magnetically active agents in the area of interest at the beat frequency created by the interference of the dual beam ultrasound;
iii. detecting biomagnetic signal by magnetometer such as a SQUID;
iv. applying a modulation to the area of interest to allow phase sensitive detection,
v. localizing loci within the area of interest using an ultrasound probe for data registration, and
vi. transforming the data from step (v) into a data form which indicates presence of nanoparticles at the target location.

Referring now to FIG. 10, the above method and apparatus are illustrated graphically 1000. The figure includes a dual bean ultrasonic transmitter 1002 directed into a location 1004 in an area of interest 1006 of an animal, including an human containing an amount of magnetically active agents such as magnetically active nanoparticles. The dual beam transmitters 1002 produces a mechanical vibration in the location having a frequency Δω equal to the difference between the two base frequencies ω₁ and ω₂, i.e., Simultaneously, the location is be modulated by application of a controlled external magnetic field from coils 1008. A magnetic sensor 1010, in this case a SQUID, is positioned adjacent the location 1004 and designed to measure a magnetic field distribution of the location 1004. A signal 1012 from the sensor 1010 is forwarded to an electronics unit 1014 to produce a data signal 1016 which is subjected to a fast Fourier transform analysis in a FFT analyzer 1018 to form a data output 1020 that can then be graphically outputted 1022 to display device or a printing device. The method and apparatus takes advantages of lock-in amplifiers and lock-in detections data processing to improve signal to noise and to improve the detection of weak magnetic signals associated with the magnetically active agents accumulating at different rates and to different concentration in location within an area of interest in an animal's body.

The methods and instruments of this invention allow for the detection of areas of injury and infarction of myocardium, liver lesions and tumors, atherosclerotic plaque and other target locations in a body. The methods of this invention can also include the step of positioning the sensor at a first location and moving the sensor along a path to a second position and acquiring a series of magnetic field distributions along the path. The acquisition can be continuous or intermittent, occurring only at discrete intervals along the path. This type of method is ideally suited for coronary arteries and acquiring magnetic field distribution of the heart muscle and arterial walls.

All references cited herein are incorporated by reference. The foregoing disclosure and description of the invention are illustrative and explanatory. Various changes in the size, shape, and materials, as well as in the details of the illustrative construction may be made without departing from the spirit of the invention. Although the invention has been disclosed with reference to its preferred embodiments, from reading this description those of skill in the art may appreciate changes and modification that may be made which do not depart from the scope and spirit of the invention as described above and claimed hereafter.

1. (canceled)

2. The method of claim 1, wherein the magneto sensor comprises a magnetooptical sensor, a flux gate magnetometer, an Hall effect sensor, a magnetic force sensor, a magnetoresistive sensor, a magnetoinductive sensor, a magneto-resonance sensor, a superconducting quantum interference device (SQUID) and mixtures or combinations thereof.

3. The method of claim 1, wherein the AOIs are selected from the group consisting of a region comprising ischemia, infarction, injury, inflammation, infection, tumor, bleeding, angiogenesis, abnormally high blood barrier permeability, abnormally high capillary permeability, clot formation and vulnerable plaque.

4. The method of claim 1, wherein the magnetic substances comprises particles and/or nanoparticles.

5. (canceled)

6. (canceled)

7. (canceled)

8. (canceled)

9. (canceled)

10. The method of claim 1, further comprising the step of:
while measuring, applying an external magnetic field.

11. (canceled)

12. (canceled)

13. (canceled)

14. The method of claim 10, wherein the external magnetic field is nonsteady.

15. The method of claim 10, wherein the external magnetic field is steady.

16. The method of claim 10, wherein the external magnetic field is produced via an external magnetic field coil.

17. (canceled)

18. The method of claim 10, further comprising the step of:
changing a property of the applied external magnetic field, the property is selected from the group consisting of direction, intensity and duration.

19. (canceled)

20. The method of claim 48, wherein the diagnostic image is an ultrasonography image, a computed tomography image, an X-ray image, or an magnetic resonance image.

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. A method for identifying loci in an animal that accumulate magnetic substance comprising the steps of:
placing an animal on an examination apparatus including a magneto sensor located external to the animal adjacent an area of interest (AOI) of the animal,
administering a magnetic substance to the animal,
measuring a first magnetic field distribution in the animal at the AOI with the magneto sensor, and
determining an amount of the magnetic substance in the AOI of the animal from the distribution.

46. The method of claim 45, further comprising the step of:
measuring a second magnetic field distribution in the AOI with the magneto sensor, prior to the administering step,
comparing the first and second magnetic field distributions, and
determining the AOIs that have an amount of the magnetic substance above a threshold value.

47. The method claim 45, wherein the sensor is moveable and the method further comprising the step of:
moving the magneto sensor to a different AOI of the animal;
repeating steps of claim 1 and the moving step, and
determining the AOIs that have an amount of the magnetic substance above a threshold value.

48. The method of claim 45, further comprising the step of:
while the measuring the distribution, making a diagnostic image of the AOI.

49. The method of claim 45, further comprising the step of:
while the measuring the distribution, exciting the AOI with ultrasound energy.

50. The method of claim 45, further comprising the step:
inducing a stress in the animal, prior to measuring the first distribution.

51. The method of claim 45, further comprising the step:
inducing a stress in the animal, and
measuring a third magnetic field distribution in the AOI with the magneto sensor.

52. A method for measuring weak magnetic field perturbations due to locally accumulation of a magnetically active agent at loci in an animal comprising the steps of:
i. placing a magnetomer proximate to an area of interest of an animal, including an human;
ii. monitoring cardiac activity electrically or magnetically of the animal;
iii. determining a beginning of a trigger signal interval, tₒ by analyzing a cardiac cycle waveform of the animal;
iv. determining a duration, t_{d} of the trigger signal interval;
v. generating a trigger signal waveform using parameters determined in steps (iii) and (iv);
vi. transmitting the trigger signal waveform to an arbitrary-form signal generator in order to generate an excitation signal waveform of chosen duration at the end of trigger;
vii. transmitting the excitation signal waveform through an excitation coil setup in order to achieve a required polarization of magnetic moments of magnetic agent;
viii. repeating steps (ii) through (vii);
ix. detecting a biomagnetic signal at the magnetometer;
x. extracting data from the selected interval of the cardiac cycle that equals a length of the excitation signal waveform; and
xi. transforming the data from step (x) into a data form which indicates presence of the agent at the target location.

53. A method for measuring weak magnetic field perturbations due to locally accumulation of a magnetically active agent at loci in an animal comprising the steps of:
i. placing magnetomer proximate to an area of interest (AOI) of an animal, including an human;
ii. exciting the AOI with acoustic radiation energy with a dual beam ultrasonic transmitter probe adapted to generate a mechanical vibration of the agent in the AOI at a beat frequency created by an interference of the dual beam ultrasound;
iii. detecting a biomagnetic signal with the magnetometer,
iv. applying a modulation to the AOI to allow phase sensitive detection,
v. localizing loci within the AOI using the probe for data registration, and
vi. transforming the data from step (v) into a data form which indicates a presence of the agent in the loci of the AOI.

54. A magneto sensor detection system comprising:
an examination surface including an opening; and
a magneto sensor mounted below the surface in the opening.

55. The system of claim 54, wherein the surface further includes a magnetic shield.

56. The system of claim 54, further comprising:
a magnetic shield mounted to the surface.

57. The system of claim 56, wherein the shield is moveable between a first position and a second position different from the first position, where the first position is adapted to be above and adjacent to an animal positioned on the examination surface.

58. The system of claim 57, further comprising:
at least two magnetizing coils mounted to the examination surface.

59. The system of claim 58, wherein the magnetizing coils are moveable with respect to the examination surface and the sensor.

60. The system of claim 54, wherein the system is portable.

61. The system of claim 54, wherein the sensor is rotatably mounted in the opening so that the sensor is capable of traversing a closed loop path about the AOI.

62. The system of claim 61, wherein the closed loop path is a circular path.

63. The system of claim 54, wherein the surface further includes a first end, a second end opposite the first end, a longitudinal axis extending from the first end to the second end, and a slot adapted to allow the opening and the sensor mounted therein to move within the slot.

64. The system of claim 63, wherein the slot is laterally disposed on a portion of the surface so that the sensor is moveable laterally.

65. The system of claim 63 wherein the slot is longitudinally disposed or disposed parallel to the longitudinal axis so that the sensor is moveable longitudinally.

66. The system of claim 63 wherein the slot is longitudinally disposed or disposed parallel to the longitudinal axis and includes lateral extensions so that the sensor is moveable longitudinally and laterally.

67. A magneto sensor detection system comprising:
a chair including
a first substantially horizontally oriented surface, and
a second substantially vertically surface including an opening therein, and
a magnetic sensor mounted in the opening.

68. The system of claim 67, wherein the second surface further including a magnetic shield.

69. The system of claim 67, wherein the sensor is moveable so that the sensor can be positioned adjacent to an heart of a patient seated on the first surface.
